(19) United States
(12) Patent Application Publication
(10) Pub. No.: US 2014/0333353 A1
(43) Pub. Date: Nov. 13, 2014

(54) MANAGING CLOCK AND RECOVERY DATA

(71) Applicant: Broadcom Corporation, Irvine, CA (US)

(72) Inventor: Dae Woon Kang, Chandler, AZ (US)

(73) Assignee: Broadcom Corporation, Irvine, CA (US)

(21) Appl. No.: 13/900,078

(22) Filed: May 22, 2013

Related U.S. Application Data
(60) Provisional application No. 61/822,625, filed on May 13, 2013.

(51) Int. Cl. H03L 7/06

(52) U.S. Cl. CPC H03L 7/06
USPC 327/156; 327/155

(57) ABSTRACT

Disclosed are various embodiments for a clock and data recovery (CDR) system. The CDR system comprises a transition detection stage and a clock recovery stage. The transition detection stage is responsible for receiving the data signal and detecting whether a transition exists in the data signal by oversampling the data signal. The clock recovery stage generates a recovery clock based on whether there is a transition in the data signal.

### CROSS-REFERENCE TO RELATED APPLICATIONS

This application claims the benefit of U.S. Provisional Application No. 61/822,625, filed May 13, 2013, the entire contents of which are hereby incorporated herein by reference.

### BACKGROUND

Data may be transmitted by a transmitter and received by a receiver. The data may be formatted as a digital signal that is synchronized to a timing reference such as a clock. According to some transmission protocols, the digital data signal received by the receiver is received without the timing reference. In this respect, the receiver and the transmitter do not share a common clock. To handle the received digital data signal, the receiver performs a clock and data recovery (CDR) on the received digital data signal. By performing CDR on the digital data signal, a clock is extracted from the digital data signal.

### BRIEF DESCRIPTION OF THE DRAWINGS

Many aspects of the present disclosure can be better understood with reference to the following drawings. The components in the drawings are not necessarily drawn to scale, emphasis instead being placed upon clearly illustrating the principles of the disclosure. Moreover, in the drawings, like reference numerals designate corresponding parts throughout the several views.

FIG. 1 is a drawing of an example of a communication system, according to various embodiments of the present disclosure.

FIG. 2A is a drawing of components in the receiver of the communication system of FIG. 1, according to various embodiments of the present disclosure.

FIG. 2B is a drawing of components in the receiver of the communication system of FIG. 1, according to various embodiments of the present disclosure.

FIG. 3A is a drawing of an example of a timing diagram of a signal processed by the receiver of the communication system of FIG. 1, according to various embodiments of the present disclosure.

FIG. 3B is a drawing of an example of a timing diagram of a signal processed by the receiver of the communication system of FIG. 1, according to various embodiments of the present disclosure.

FIG. 3C is a drawing of an example of a timing diagram of a signal processed by the receiver of the communication system of FIG. 1, according to various embodiments of the present disclosure.

FIG. 4 is a flowchart illustrating one example of functionality implemented as portions of a clock and data recovery system of the receiver of the communication system of FIG. 1, according to various embodiments of the present disclosure.

### DETAILED DESCRIPTION

The present disclosure relates to performing clock and data recovery (CDR) on an incoming digital data signal. A CDR system receives an incoming digital data signal as a stream. The digital data signal is received as a serial link without any timing reference. That is to say, the incoming digital data signal is received without being synchronized according to a clock. The CDR system is operable to recover the data that is expressed in the digital data signal. The CDR system also extracts timing information from the incoming digital data signal such as a recovery clock, where the recovery digital data signal is synchronized to the recovery clock.

According to various embodiments, the CDR system comprises a transition detection stage and a clock recovery stage. The transition detection stage is responsible for receiving the digital data signal. Prior to transmission and reception, the digital data signal may be associated with an original clock having an original clock period. This original clock is not shared with the receiver.

The transition detection stage is responsible for sampling the digital data signal according to an internal reference clock. The internal reference clock may be generated by the CDR system such that the clock period of the internal reference clock is substantially shorter than the original clock period of the original clock. In this respect, the digital data signal is oversampled in the transition detection stage according to an internal reference clock that has a relatively short clock period with respect to the original clock period. The transition detection stage is operable to detect a transition in the digital data signal by performing multiple samples and detecting whether a difference between the multiple samples exists. Thus, the transition detection stage dynamically determines when the data transitions occur in the digital data signal.

In some embodiments, the transition detection stage comprises a data synch stage for reducing metastability in the incoming digital data signal. Metastability refers to a condition where a signal is unstable. For example, a bit in a signal may be unable to settle to a “1” or a “0.” The data synch stage may comprise, for example, cascaded flip-flops that receive the internal reference clock as a clock input to reduce metastability.

The clock recovery stage is operable to generate a recovery clock. The recovery clock is generated based on whether a transition exists in the digital data signal.

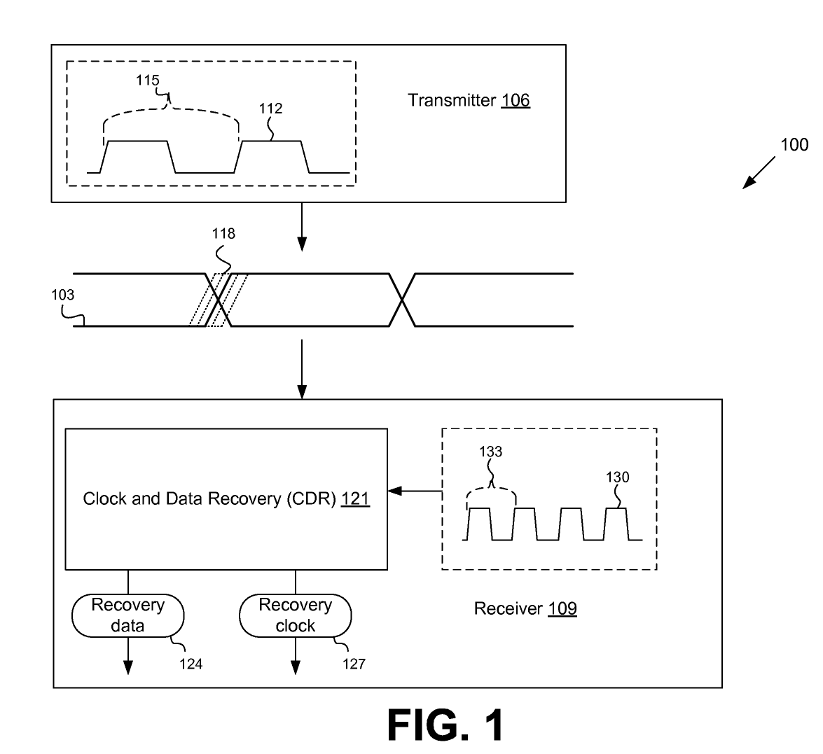

With reference to FIG. 1, shown is a communication system 100 that facilitates a communication of a data signal 103. The data signal 103 may be a stream of data expressed as a sequence of bits. Thus, the data signal 103 may be formatted in the digital domain. The communication system 100 includes a transmitter 106. The transmitter 106 may be implemented using one or more circuits, one or more microprocessors, application-specific integrated circuits, dedicated hardware, digital signal processors, microcomputers, central processing units, field programmable gate arrays, programmable logic devices, state machines, or any combination thereof. In yet other embodiments, the transmitter 106 may include one or more software modules executable within one or more processing circuits. For example, the transmitter 106 may include memory configured to store instructions and/or code that causes processing circuitry to execute data communication functions.

The transmitter 106 may be operable to handle data that is synchronized according to an original clock 112. The original clock 112 may have an original clock period 115. In this respect, the transmitter 106 may handle data signals according to a data communication protocol, where the data communication protocol defines an original clock period 115.

The transmitter 106 is operable to transmit the data signal 103. Through the transmission process, the data signal 103 may experience jitter 118 or any other timing abnormalities that cause the data signal 103 to deviate from the original clock 112 at a point in time after the transmission of the data signal 103.

The data signal 103 is received by a receiver 109. The receiver 109 may be implemented using one or more circuits, one or more microprocessors, application-specific integrated circuits, dedicated hardware, digital signal processors, microcomputers, central processing units, field programmable gate arrays, programmable logic devices, state machines, or any combination thereof. In yet other embodiments, the receiver 109 may include one or more software modules executable within one or more processing circuits. For example, the receiver 109 may include memory configured to store instructions and/or code that causes processing circuitry to execute data communication functions.

The receiver 109 includes a clock and data recovery (CDR) system 121. The CDR system 121 is responsible for generating a recovery data signal 124 based on the incoming data signal 103. The recovery data signal 124 includes the substantive information expressed in the data signal 103. The CDR system 121 is also responsible for generating a recovery clock 127 based on the incoming data signal 103, where the recovery data signal 124 is synchronized to the recovery clock 127.

The CDR system 121 of the receiver 109 handles incoming data signals 103 using an internal reference clock 130. The internal reference clock 130 may be generated by the CDR system 121 or generated by the receiver 109. In either case, the internal reference clock 130 is used by the CDR system 121 to generate the recovery data signal 124 and the recovery clock 127. The internal reference clock 130 has a reference clock period 133.

Next, a general description of the operation of the various components of the communication system 100 is provided. To begin, the data signal 103 may be communicated from a transmitter 106 to a receiver 109. The transmitter 106 prepares the data signal 103 for transmission. The transmitter 106 processes the data signal 103 according to the original clock 112. In this respect, prior to transmission, the data signal 103 may be synchronized according to an original clock 112. The original clock 112 may have an original clock period 115 of n*x. The original clock period 115 may be defined by any data communication protocol.

The transmitter 106 transmits the data signal 103 to a receiver 109 using a serial link. The serial link may comprise, for example, a wired link, a wireless link, or any other communication channel. The transmitter 106 does not transmit the original clock 112 with the data signal 103.

The receiver 109 receives the data signal 103 without receiving any timing reference such as the original clock 112. In this respect, the original clock 112 is not shared or is not in common with the receiver 109. The receiver 109 may communicate with the transmitter 106 using a predefined data communication protocol. Although some characteristics of the original clock 112, such as the original clock period 133, may be used by the receiver 109, the actual signal of the original clock 112 is not used by the receiver 109 nor is it transmitted to the receiver 109.

According to various embodiments, the CDR system 121 receives an internal reference clock 130. The internal reference clock 130 may be generated by the CDR system 121 or generated by the receiver 109. In either case, the internal reference clock 130 is used by the CDR system 121 to generate the recovery data signal 124 and the recovery clock 127.

The internal reference clock 130 has a reference clock period 133 of x while the original clock period 115 is n*x, where n is greater than 1. Thus, the reference clock period 133 is n times shorter than the original clock period 115. The variable n is a factor amount that describes the relationship between the internal reference clock 130 and the original clock 112. To this end, the internal reference clock 130 is n times faster than the original clock 112. In various embodiments, n is equal to a power of two such as, for example, 4, 8, 16, etc.

The non-limiting examples discussed below use a value of n that is equal to 4. Although the non-limiting examples discussed below set the value of n to 4, it is understood that any value of n may be used within the spirit and scope of the present disclosure.

By using the internal reference clock 130, the CDR system 121 recovers the data signal 103 by generating a recovery data signal 124. The CDR system also generates a recovery clock 127, where the recovery data signal 124 is synchronized to the recovery data signal 124.

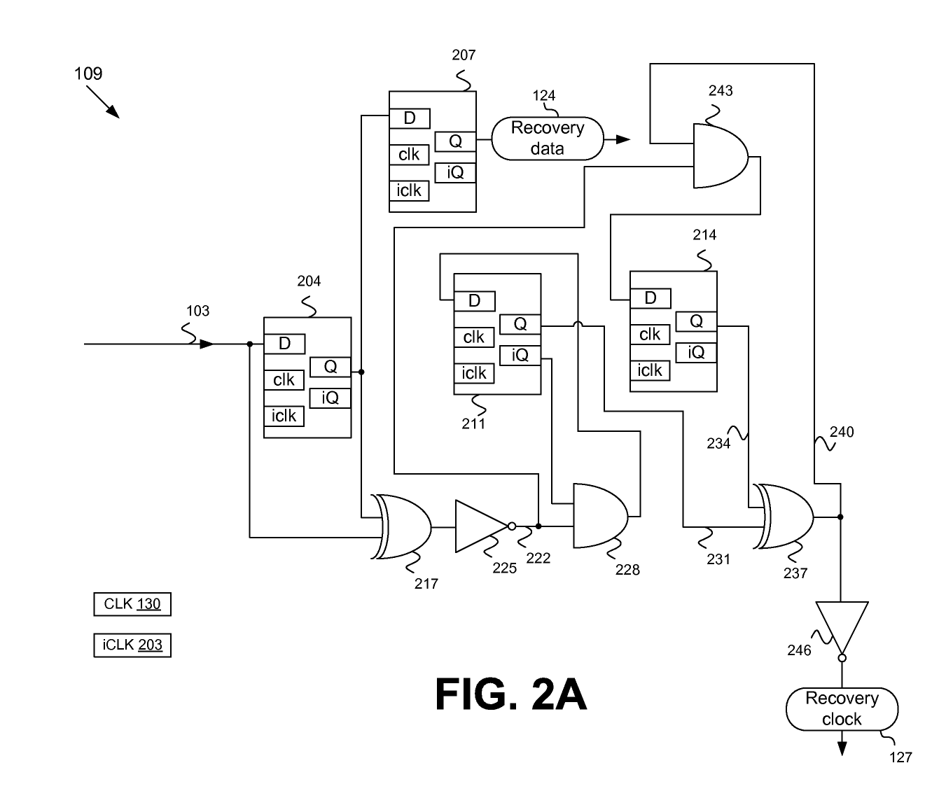

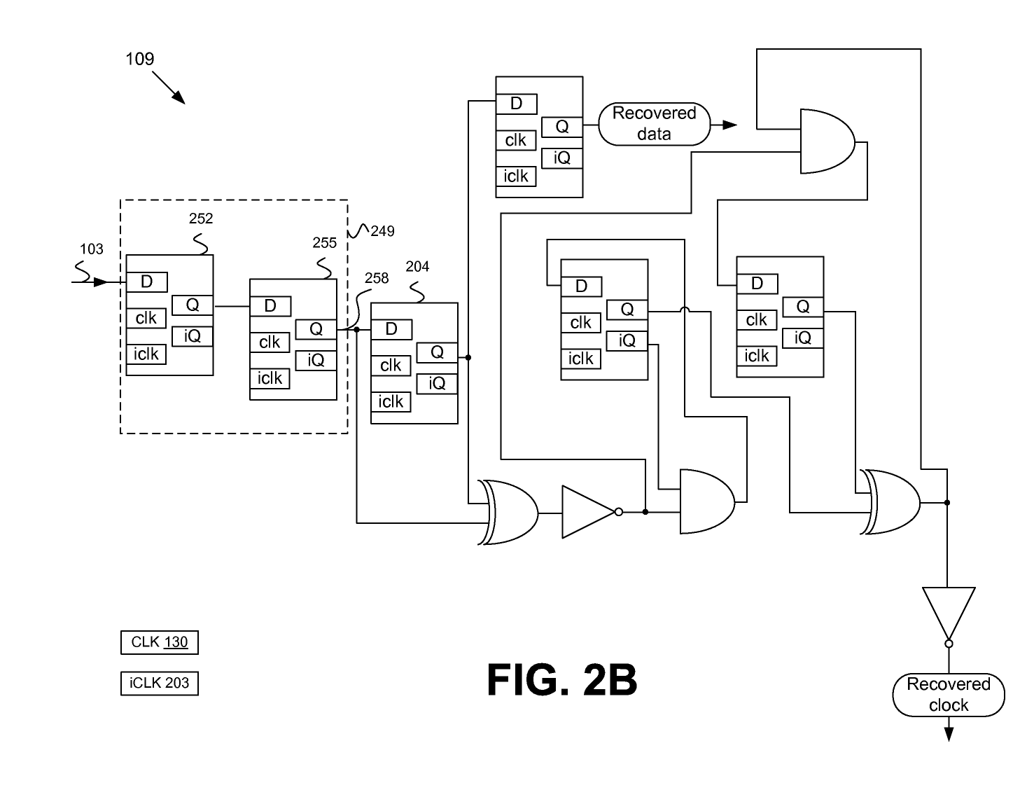

With reference to FIG. 2A, shown is a drawing of components in the receiver 109 of the communication system 100 of FIG. 1, according to various embodiments of the present disclosure. Specifically, FIG. 2A depicts components of a CDR system 121 (FIG. 1) that is operable to generate a recovery data signal 124 and a recovery clock 127 based on a data signal 103. The CDR system 121 may include multiple sequential logic elements 204, 207, 211, 214 that receive a clock such as the internal reference clock 130. A sequential logic element 204, 207, 211, 214 may be, for example, a flip-flop or any other state machine element that may be synchronized to a clock.

A sequential logic element 204, 207, 211, 214 may include a data input, referred to as “D,” a clock input, referred to as “CLK,” an inverted clock, referred to as “iCLK,” an output, referred to as “Q,” and an inverted output, referred to as “iQ.” As depicted in FIG. 2A, various sequential logic elements 204, 207, 211, 214 may receive a clock input CLK from an internal reference clock 130 and/or an inverted clock input iCLK from an inverted clock 203. The inverted clock 203 may be an inverted version of the internal reference clock 130.

The CDR system 121 comprises a sequential logic element 204 that receives the data signal 103 via a data input, D. The output, Q, of the sequential logic element 204 is coupled to the input, D, of another sequential logic element 207. The output of the other sequential logic element 207 is referred to as the recovery data 124.

The output, Q, of the sequential logic element 204 is also coupled to a logic gate 217. The output of the logic gate 217 may be inverted by an inverter 225. The output of the inverter 225 may be referred to a phase reset signal 222. The CDR system 121 comprises a logic gate 228 that receives the phase reset signal 222 and an output of a first stage sequential logic element 211. The output of the logic gate 228 is supplied to the input of the first stage sequential logic element 211.

An output of the first stage sequential logic gate may be referred to as a first stage output signal 231. A logic gate 237 receives the first stage output signal 231 as an input. The logic gate 237 also receives a second stage output signal 234 as an input, where the second stage output signal 234 is generated by a second stage sequential logic element 214. The output of the logic gate 237 may be referred to as a phase detection signal 240. A logic gate 243 receives the phase detection signal 240 as an input and also receives the phase reset signal 222 as another input. The output of the logic gate 243 is supplied to the input of the second stage sequential logic element 214. The recovery clock 127 is generated by inverting the phase detection signal 240 using an inverter 246.

Next, a general description of the operation of the various components of the communication system 100 is provided. To begin, the CDR system 121 comprises a transition detection stage that is operable to detect a transition in the data signal 103. The transition detection stage may include a sequential logic element 204 that is configured to detect transitions in the data signal 103. This sequential logic element 204 samples the data signal 103 according to the internal reference clock 130. Because the internal reference clock 130 has a reference clock period 133 (FIG. 1) that is substantially shorter than the original clock period 115 (FIG. 1) that was initially associated with the data signal 103, the sequential logic element 204 oversamples the data signal 103.

The sequential logic element 204 may be arranged to compare a first sample of the data signal 103 with a second sample of the data signal 103 to determine whether a transition exists in the data signal 103. For example, the transition detection stage may comprise a logic gate 217 that is used to compare the first sample of the data signal 103 with the second sample of the data signal 103. The logic gate 217 may be an XOR logic gate that detects whether the first sample is equal to the second sample. As depicted in FIG. 2A, the logic gate 217 receives the first sample which is the data signal 103. The logic gate 217 also receives a second sample which is the data signal 103 that has been delayed by the sequential logic element 204. This delay corresponds to the reference clock period 133.

The transition detection stage of the CDR system 121 generates a phase reset signal 222 based on sampling the data signal 103 according to the internal reference clock 130. The phase reset signal 222 indicates whether a transition in the data signal 103 exists. The phase reset signal 222 is generated at the output of the logic gate 217. In some cases, the phase reset signal 222 may be inverted by an inverter 225.

The CDR system 121 may generate a recovery data signal 124 by using the output of the sequential logic element 204 of the transition detection stage and by using a following sequential logic element 207. Thus, the recovery data signal 124 may be generated by cascading at least two sequential logic elements 204, 207, where the cascaded sequential logic elements 204, 207 receive the internal reference clock 130. The CDR system 121 may further include a clock recovery stage to generate the recovery clock 127. The clock recovery stage may comprise a first stage sequential logic element 211 and a second stage sequential logic element 214. The first stage sequential logic element 211 may comprise a feedback loop where the input (e.g., D) depends on the output (e.g., Q, iQ, etc.). Furthermore, the input may be based on the phase reset signal 222. As shown in FIG. 2A, the input to the first stage sequential logic element 211 is based on a combination of the iQ and the phase reset signal 222. This combination may be generated using a logic gate 228 such as, for example, an AND logic gate. The first stage sequential logic element 211 generates a first stage output signal 231.

The second stage sequential logic element 214 may comprise a feedback loop where the input (e.g., D) depends on the output (e.g., Q, iQ, etc.). Furthermore, the input may be based on the phase reset signal 222, the first stage output signal 231, and the second stage output signal 234. As shown in FIG. 2A, the input to the first stage sequential logic element 211 is based on a combination of the first stage output signal 231 and the second stage output signal 234. For example, a logic gate 237 may be used to detect a difference between the first stage output signal 231 and the second stage output signal 234. The logic gate 237 may comprise an XOR logic gate to determine whether there is a difference between the first stage output signal 231 and the second stage output signal 234. A phase detection signal 240 indicates whether a difference between the first stage output signal 231 and the second stage output signal 234 exists. Additionally, the clock recovery stage comprises a logic gate 243 that combines the phase reset signal 222 with the phase detection signal 240. This logic gate 243 may comprise an AND logic gate that sends the output to the input of the second stage sequential logic element 214.

The recovery clock 127 is generated based on detecting a difference between the first stage output signal 231 and the second stage output signal 234. In some embodiments, the output of the logic gate 237 that detects this difference is inverted by an inverter 246.

Moving to FIG. 2B, shown is a drawing of components in the receiver 109 of the communication system 100 of FIG. 1, according to various embodiments of the present disclosure. Specifically, FIG. 2B depicts a CDR system 121 (FIG. 1) that is operable to generate a recovery data signal 124 and a recovery clock 127 based on a data signal 103, where the CDR system 121 addresses metastability. Similar to FIG. 2A, the CDR system 121 of FIG. 2B includes a transition detection stage that includes a sequential logic element 204 that is configured to detect transitions in the data signal 103.

The CDR system 121 of FIG. 2B further includes metastability circuitry 249 to reduce the occurrence of metastability that may exist in the data signal 103. The metastability circuitry 249 may include a first sequential logic element 252 and a second sequential logic element 255. These sequential logic elements 252, 255, may include a data input, referred to as “D,” a clock input, referred to as “CLK,” an inverted clock, referred to as “iCLK,” an output, referred to as “Q,” and an inverted output, referred to as “iQ.” As depicted in FIG. 2B, various sequential logic elements 252, 255 may receive a clock input CLK from an internal reference clock 130 and/or an inverted clock input iCLK from an inverted clock 203. The first sequential logic element 252 and the second sequential logic element 255 may be cascaded to reduce metastability in the data signal 103.

The metastability circuitry 249 processes the data signal 103 to generate a synchronized data signal 258, where the synchronized data 258 signal may have reduced metastability. The synchronized data signal 258 is supplied to the sequential logic element 204 of the transition detection stage as an input.

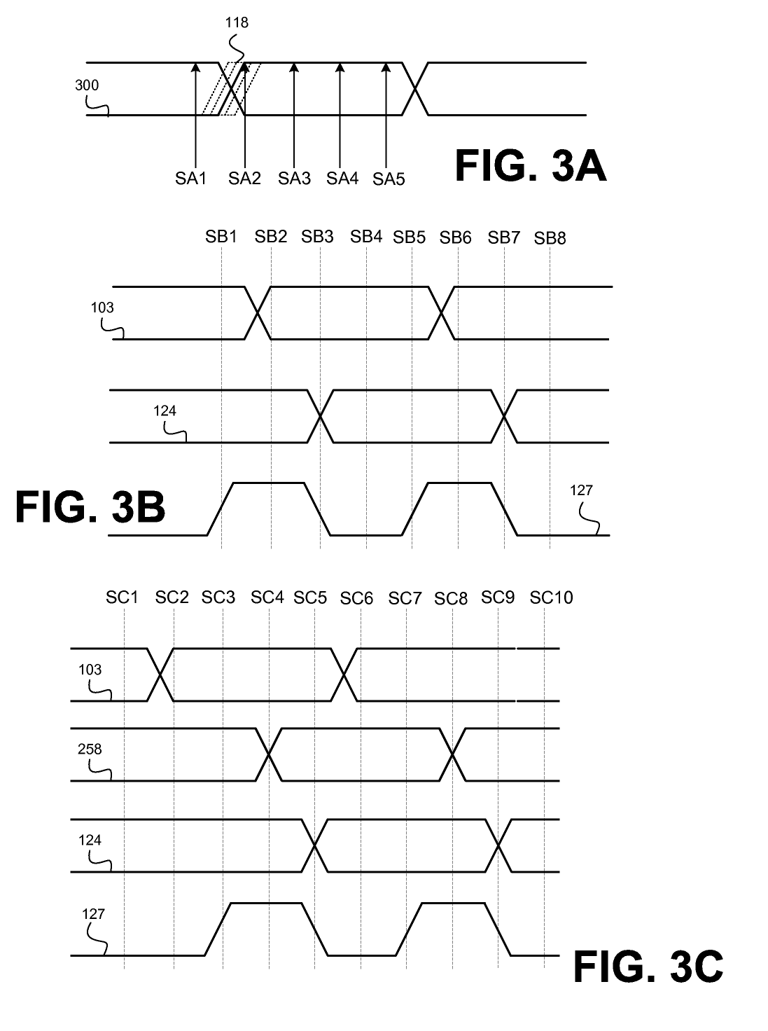

Turning to FIG. 3A, shown is a drawing of an example of a timing diagram of a signal 300 processed by the receiver 109 of the communication system 100 of FIG. 1, according to various embodiments of the present disclosure. The signal 300 may be a data signal 103 received by a receiver 109 as depicted in FIG. 2A. The signal 300 may also be a synchronized data signal 258 that has been processed by the metastability circuitry 249 of FIG. 2B. In either case, the signal 300 is received by a sequential logic element 214 (FIGS. 2A, 2B) of a transition detection stage of a CDR system 121 (FIG. 1).

The signal 300 may experience jitter 118 as the signal 300 is transmitted from a transmitter 106 (FIG. 1) to a receiver 109 (FIG. 1). The signal 300 is processed by the CDR system 121 to generate a recovery data signal 124 (FIG. 1) and/or a recovery clock 127 (FIG. 1). The CDR system 121 oversamples the signal 300 according to a reference clock period 133 (FIG. 1). FIG. 3A depicts five sample points SA1-SA5 that are separated by a sampling interval. The sampling interval corresponds to the reference clock period 133.

A logic gate 217 (FIG. 2A) may compare a first sample at a first sample point SA1 with a second sample at a second sample point SA2 to detect a transition in the signal 300. The second sample may be a delayed version of the first sample where the delay is generated using a sequential logic element 204.

Next, FIG. 3B depicts an example of a timing diagram of a signal processed by the receiver 109 of the communication system 100 of FIG. 1, according to various embodiments of the present disclosure. Specifically, the signal is a data signal 103 that is processed by the receiver 109 depicted in FIG. 2A. FIG. 3B depicts eight sample points SB1-SB8 separated by the sampling interval. A first sample of the data signal 103 is compared to a second sample of the data signal 103 to detect a transition in the data signal 103. As shown in FIG. 3B, a transition is detected between a first sample point SB1 and a second point SB2. At a third sample point SB3, the recovery data signal 124 is generated. That is to say, the transition in the data signal 103 that occurs between the first sample point SB1 and the second point SB2 is reflected at the third sample point SB3. A recovery clock 127 is generated by the CDR system 121 such that the recovery data signal 124 is synchronized to the recovery clock 127.

Regarding FIG. 3C, shown is an example of a timing diagram of a signal processed by the receiver 109 of the communication system 100 of FIG. 1, according to various embodiments of the present disclosure. Specifically, the signal is a data signal 103 that is processed by the metastability circuitry 249 (FIG. 2B) to generate a synchronized data signal 258. FIG. 3C depicts ten sample points SC1-SC10 that are separated by the sampling interval. As depicted in FIG. 3C, the synchronized data signal 258 is a delayed version of the data signal 103. The delay amount is dependent on the reference clock period 133 (FIG. 1) and the metastability circuitry 249. While the data signal 103 is not aligned to the internal reference clock 130 (FIG. 1), the synchronized data signal 258 is aligned to the internal reference clock 130.

A first sample of the synchronized data signal 258 is compared to a second sample of the synchronized data signal 258 to detect a transition in the synchronized data signal 258. As shown in FIG. 3C, a transition of the synchronized data signal 258 is detected at a fourth sample point SC4. At a fifth point, the recovery data signal 124 is generated. The transition in the data signal 103 that occurs between the first sample point SC1 and the second sample point SC2 is reflected at the fifth sample point SC5. A recovery clock 127 is generated by the CDR system 121 such that the recovery data signal 124 is synchronized to the recovery clock 127.

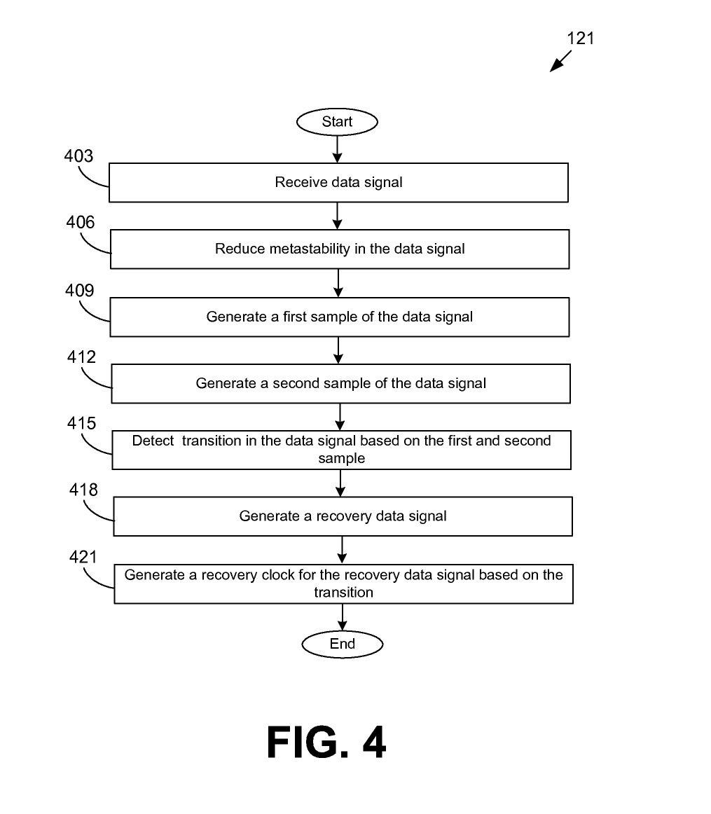

Turning now to FIG. 4, shown is a flowchart that provides an example of operation of a portion of the logic executed by the CDR system 121 of FIG. 1, according to various embodiments. It is understood that the flowchart of FIG. 4 provides merely an example of the many different types of functional arrangements that may be employed to implement the operation of the portion of the logic executed by the CDR system 121 as described herein. As an alternative, the flowchart of FIG. 4 may be viewed as depicting an example of steps of a method implemented in the CDR system 121 according to one or more embodiments.

Beginning at 403, the CDR system 121 receives a data signal 103 (FIG. 1). The CDR system 121 may be implemented as a portion of a receiver 109 (FIG. 1) that receives the data signal 103 as a serial link without a timing reference. The CDR system 121 is operable to extract a clock from the data signal 103, where the extracted clock is referred to as a recovery clock 127 (FIG. 1).

At 406, the CDR system 121 reduces metastability in the data signal 103. For example, the CDR system 121 may include metastability circuitry 249 (FIG. 2B) to reduce metastability. The metastability circuitry 249 may comprise a series of sequential logic elements that align the data signal 103 to an internal reference clock 130 (FIG. 1). Thus, the various sequential logic elements of the metastability circuitry 249 may receive the internal reference clock 130 as an input.

At 409, the CDR system 121 generates a first sample of the data signal 103. In the case where metastability circuitry 249 is used, the data signal 103 may be referred to as a synchronized data signal 258 (FIG. 2B). In various embodiments, the CDR system 121 generates the first sample by using the data signal 103 as is. That is to say, the first sample may be a current value of the data signal 103 without delaying the data signal 103.

At 412, the CDR system 121 generates a second sample of the data signal 103. The second sample may be a delayed version of the data signal 103. In this respect, the second sample follows the first sample in terms of time. The difference in time is based on the reference clock period 133 (FIG. 1) of the internal reference clock 130.

At 415, the CDR system 121 detects a transition in the data signal based on the first sample and the second sample. For example, the CDR system 121 may comprises one or more logic gates 217 (FIG. 2A) that detect instances when the first sample does not equal the second sample. When the first sample does not equal the second sample, a transition in the data signal 103 exists. A phase reset signal 222 is generated at the output of the logic gate 217 or inverter 225, where the phase reset signal 222 indicates whether there is a transition in the data signal 103.

At 418, the CDR system 121 generates a recovery data signal 124. The CDR system 121 may use cascaded sequential logic elements to generate the recovery signal 124. These cascaded sequential logic elements may be synchronized to the internal reference clock 130. At 421, the CDR system 121 generates a recovery clock 127 for the recovery data signal 124 based on the transition. The CDR system 121 may comprise a clock recovery stage for generating the recovery clock 127 based on the phase reset signal 222, where the phase reset signal 222 indicates whether there is a transition in the data signal 103.

The clock recovery stage may comprise a first stage sequential logic element 211 (FIG. 2A) and a second stage sequential logic element 214 (FIG. 2A). The clock recovery stage may also comprise a logic gate 237 to detect whether there is a difference between the first stage output signal 231 of the first stage sequential logic element 211 and a second stage output signal 234 of the second stage sequential logic element 214. The output of this logic gate 237 may be referred to as a phase detection signal 240 that indicates when the first stage output signal 231 does not match the second stage output signal 234. The recovery clock 127 may be determined based on the phase detection signal 240 and the phase reset signal 222.

The flowchart of FIG. 4 shows the functionality and operation of an implementation of portions of the CDR system 121 implemented in a receiver 109 (FIG. 1). Portions of the flowchart of FIG. 4 may be embodied as software. For example, software may be used to simulate the various components discussed above with respect to at least FIG. 4. If embodied in software, each reference number, represented as a block, may represent a module, segment, or portion of code that comprises program instructions to implement the specified logical function(s). The program instructions may be embodied in the form of source code that comprises human-readable statements written in a programming language or machine code that comprises numerical instructions recognizable by a suitable execution system such as a processor in a computer system or other system. The machine code may be converted from the source code. If embodied in hardware, each block may represent a circuit or a number of interconnected circuits to implement the specified logical function(s).

Although the flowchart of FIG. 4 depicts a specific order of execution, it is understood that the order of execution may differ from that which is depicted. For example, the order of execution of two or more blocks may be scrambled relative to the order shown.

Also, two or more blocks shown in succession in FIG. 4 may be executed concurrently or with partial concurrence. Further, in some embodiments, one or more of the blocks shown in FIG. 4 may be skipped or omitted. In addition, any number of counters, state variables, warning semaphores, or messages might be added to the logical flow described herein, for purposes of enhanced utility, accounting, performance measurement, providing troubleshooting aids, etc. It is understood that all such variations are within the scope of the present disclosure.

Also, any logic or application described herein, including the CDR system 121, that comprises software or code can be embodied in any non-transitory computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

1. A method, comprising:
receiving a data signal, the data signal being received without receiving a timing reference for the data signal, wherein the data signal is associated with an original clock period;
generating an internal reference clock, wherein a clock period of the internal reference clock is less than the original clock period according to a factor amount;
detecting a transition in the data signal by sampling the data signal according to the internal reference clock;
sampling the data signal according to the internal reference clock to generate a recovery data signal; and
in response to the transition being detected, generating a recovery clock for the recovery data signal.

2. The method of claim 1, wherein detecting the transition in the data signal by sampling the data signal according to the internal reference clock comprises detecting a difference between a first sample of the data signal and a second sample of the data signal.

3. The method of claim 2, wherein at least one of the first sample of the data signal or the second sample of the data signal is generated by a sequential logic element.

4. The method of claim 1, wherein generating the recovery clock for the recovery data signal comprises using a first stage sequential logic element to generate a first stage output signal in response to detecting the transition.

5. The method of claim 4, wherein generating the recovery clock for the recovery data signal further comprises using a second stage sequential logic element to generate a second stage output signal in response to detecting the transition.

6. The method of claim 5, wherein generating the recovery clock for the recovery data signal further comprises detecting a difference between the first stage output signal and the second stage output signal to generate a phase detection signal.

7. The method of claim 6, wherein an input of the second stage sequential logic element is responsive to the transition and the phase detection signal.

8. A system comprising:
a clock and data recovery (CDR) circuit operable to
receive a data signal, wherein the data signal is associated with an original clock period;
receive an internal reference clock, wherein a clock period of the internal reference clock is less than the original clock period according to a factor amount;
sample the data signal according to the internal reference clock to generate a recovery data signal; and
generate a recovery clock for the recovery data signal by detecting a difference between a first sample of the data signal and a second sample of the data signal.

9. The system of claim 8, wherein the factor amount is equal to four, wherein the clock period of the internal reference clock is substantially four times shorter than the original clock period.

10. The system of claim 8, wherein the CDR circuit comprises a plurality of cascaded flip-flops that are operable to reduce a metastability in the data signal.

11. The system of claim 8, wherein the CDR circuit comprises a first stage sequential logic element operable to generate a first stage output signal, the first stage output signal being based on the difference between the first sample of the data signal and the second sample of the data signal.

12. The system of claim 11, wherein the CDR circuit comprises a second stage sequential logic element operable to generate a second stage output signal, the second stage output signal being based on the difference between the first sample of the data signal and the second sample of the data signal.

13. The system of claim 12, wherein the CDR is further operable to generate the recovery clock by detecting a difference between the first stage output signal and the second stage output signal.

14. A clock and data recovery (CDR) circuit comprising:
a transition detection stage comprises
circuitry that receives a data signal, wherein the data signal is associated with an original clock period; and
circuitry that generates a phase reset signal based on sampling the data signal according to an internal reference clock, the phase reset signal indicating a transition in the data signal, wherein a clock period of the internal reference clock is less than the original clock period according to a factor amount;
a clock recovery stage comprising circuitry that generates a recovery clock using the phase reset signal.

15. The system of claim 14, wherein the factor amount is a power of two, the factor amount being greater than two.

16. The system of claim 14, wherein the transition detection stage comprises a plurality of cascaded sequential logic elements operable to reduce a metastability in the data signal.

17. The system of claim 14, wherein the clock recovery stage comprises:
a first stage sequential logic element operable to generate a first stage output signal using the phase reset signal; and
a second stage sequential logic element operable to generate a second stage output signal using the phase reset signal.

18. The system of claim 17, wherein an input of the first stage sequential logic element comprises a feedback loop using the first stage output signal.

19. The system of claim 17, wherein an input of the second stage sequential logic element is generated by detecting a difference between the first stage output signal and the second stage output signal.

20. The system of claim 17, wherein the first stage sequential logic element comprises a first flip-flop that is operable to receive the internal reference clock, wherein the second stage sequential logic element comprises a second flip-flop that is operable to receive the internal reference clock.
